(19) United States
(12) Patent Application Publication
(10) Pub. No.: US 2026/0173465 A1
(43) Pub. Date: Jun. 18, 2026

(54) TRENCH ISOLATION STRUCTURES WITH DIFFERENT DEPTHS

(71) Applicant: GlobalFoundries Singapore Pte. Ltd., Singapore (SG)

(72) Inventors: YONG WAH SEE, Singapore (SG); GUOWEI ZHANG, Singapore (SG); EE JAN KHOR, Singapore (SG)

(21) Appl. No.: 18/978,049

(22) Filed: Dec. 12, 2024

(51) Int. Cl. H10D 62/10; H01L 21/762; H10D 62/00

(52) U.S. Cl. CPC H10D 62/115; H10D 62/01; H10W 10/0143; H10W 10/17

(57) ABSTRACT

The present disclosure generally relates to trench isolation structures for semiconductor devices. More particularly, the present disclosure relates to trench isolation structures with varying depths for electrically isolating integrated circuit (IC) components in semiconductor devices. The present disclosure provides a structure including a substrate, a first trench, a second trench, and a third trench in the substrate. The first, second, and third trenches have respective bottoms located at different depths. The structure may also include first, second, and third dielectric layers and a semiconductor layer in the trenches. The third dielectric layer is of a different material from the second dielectric layer. The second dielectric layer is of a different material from the first dielectric layer.

### FIELD OF THE INVENTION

The present disclosure generally relates to trench isolation structures for semiconductor devices. More particularly, the present disclosure relates to trench isolation structures with varying depths for electrically isolating integrated circuit (IC) components in semiconductor devices.

### BACKGROUND

Isolation trenches are commonly used in semiconductor devices (e.g., complementary metal-oxide semiconductor (CMOS), bipolar, and a combination of bipolar and CMOS (BiCMOS)) to improve the operation of transistors and other active components of the semiconductor devices. Conventional techniques enable the formation of shallow isolation trenches to isolate active semiconductor regions on the surface of a semiconductor substrate. However, with the advancement of IC device technology, the process of fabricating isolation trenches with different depths can be complex and defect-prone.

### SUMMARY

In an aspect of the present disclosure, there is provided a structure including a substrate, a first trench in the substrate, the first trench having a bottom located at a first depth, a second trench in the substrate, the second trench having a bottom located at a second depth, the second depth is lower than the first depth, the second trench also having sidewalls extending from the bottom of the first trench to join the bottom of the second trench, a third trench in the substrate, the third trench having a bottom located at a third depth, the third depth is lower than the second depth, the third trench also having sidewalls extending from the bottom of the second trench to join the bottom of the third trench, a dielectric isolation layer in the first trench, a first dielectric layer on the sidewalls and the bottom of the second trench, a second dielectric layer laterally adjacent to the dielectric isolation layer and disposed on the first dielectric layer, a third dielectric layer laterally adjacent to the second dielectric layer, and a semiconductor layer in the first trench, the second trench, and the third trench. The third dielectric layer is of a different material from the second dielectric layer. The second dielectric layer is of a different material from the first dielectric layer.

In another aspect of the present disclosure, there is provided a structure including a substrate, a first trench in the substrate, the first trench having a bottom located at a first depth, a second trench in the substrate, the second trench having a bottom located at a second depth, the second depth is lower than the first depth, the second trench also having sidewalls extending from the bottom of the first trench to join the bottom of the second trench, a third trench in the substrate, the third trench having a bottom located at a third depth, the third depth is lower than the second depth, the third trench also having sidewalls extending from the bottom of the second trench to join the bottom of the third trench, a dielectric isolation layer in the first trench, a first dielectric layer on the sidewalls and the bottom of the second trench, the first dielectric layer is in direct contact with the dielectric isolation layer, a second dielectric layer in direct contact with the first dielectric layer, a third dielectric layer in direct contact with the second dielectric layer, and a semiconductor layer in the first trench, the second trench, and the third trench. The third dielectric layer is of a different material from the second dielectric layer. The second dielectric layer is of a different material from the first dielectric layer.

In yet another aspect of the present disclosure, there is provided a structure including a substrate, a first trench in the substrate, the first trench having a bottom located at a first depth, a second trench in the substrate, the second trench having a bottom located at a second depth, the second depth is lower than the first depth, the second trench also having sidewalls extending from the bottom of the first trench to join the bottom of the second trench, a third trench in the substrate, the third trench having a bottom located at a third depth, the third depth is lower than the second depth, the third trench also having sidewalls extending from the bottom of the second trench to join the bottom of the third trench, a first width between the sidewalls of the first trench, a second width between the sidewalls of the second trench, the second width is smaller than the first width, a third width between the sidewalls of the third trench, the third width is smaller than the second width, a dielectric isolation layer in the first trench, a first dielectric layer on the sidewalls and the bottom of the second trench, a second dielectric layer laterally adjacent to the dielectric isolation layer and disposed on the first dielectric layer, a third dielectric layer laterally adjacent to the second dielectric layer, and a semiconductor layer in the first trench, the second trench, and the third trench. The third dielectric layer is of a different material from the second dielectric layer. The second dielectric layer is of a different material from the first dielectric layer.

### BRIEF DESCRIPTION OF THE DRAWINGS

The present disclosure may be understood by reference to the following description taken in conjunction with the accompanying drawings.

For simplicity and clarity of illustration, the drawings illustrate the general manner of construction, and certain descriptions and details of certain features and techniques may be omitted to avoid unnecessarily obscuring the discussion of the described embodiments of the present disclosure. Additionally, elements in the drawings are not necessarily drawn to scale. For example, the dimensions of some of the elements in the drawings may be exaggerated relative to other elements to help improve understanding of embodiments of the present disclosure. The same reference numerals in different drawings denote the same elements, while similar reference numerals may, but do not necessarily, denote similar elements.

FIG. 1 is a cross-sectional view of an example of a structure for a semiconductor device.

FIG. 1A is an enlarged cross-sectional view of a portion of the structure shown in FIG. 1.

FIG. 2 is a top-down view of the structure shown in FIG. 1.

FIG. 3 is a cross-sectional view of another example of a structure for a semiconductor device.

FIG. 3A is an enlarged cross-sectional view of a portion of the structure shown in FIG. 3.

FIG. 4 is a top-down view of the structure shown in FIG. 3.

FIG. 5 through FIG. 12 are cross-sectional views depicting structures at various stages of a method of forming the exemplary structure shown in FIG. 1.

FIG. 13 through FIG. 18 are cross-sectional views depicting structures at various stages of a method of forming the exemplary structure shown in FIG. 3.

### DETAILED DESCRIPTION

Various illustrative embodiments or implementations of the present disclosure are described below. The embodiments or implementations disclosed herein are exemplary and not intended to be exhaustive or limiting to the present disclosure.

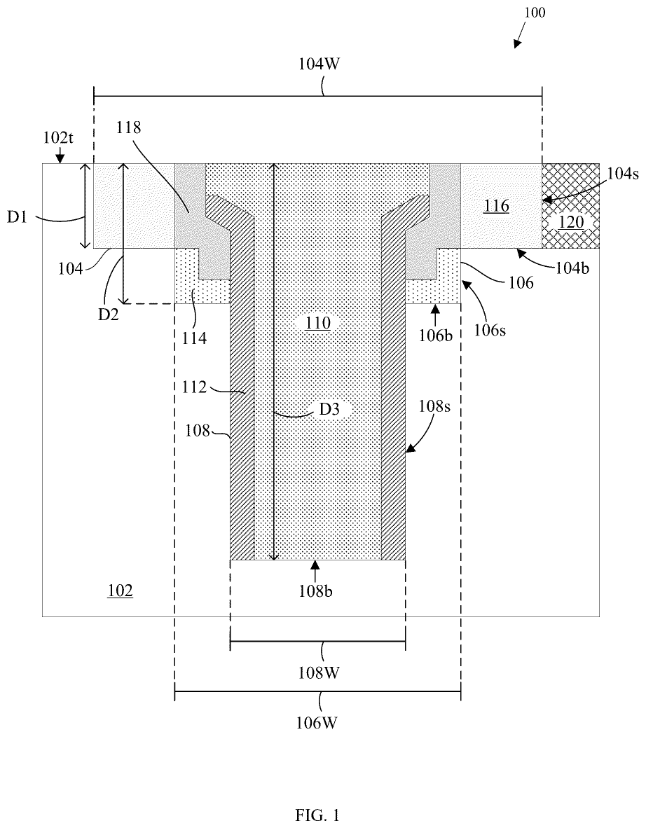

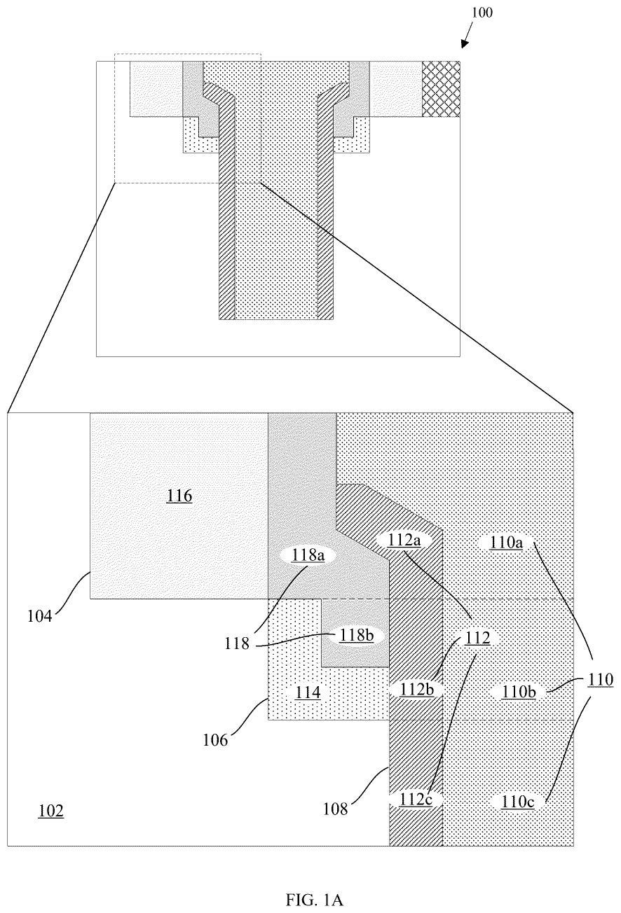

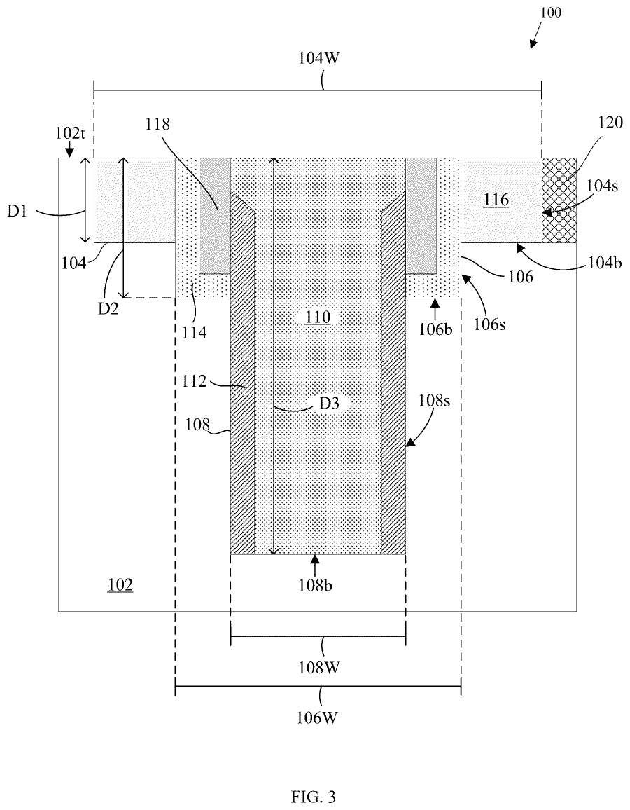

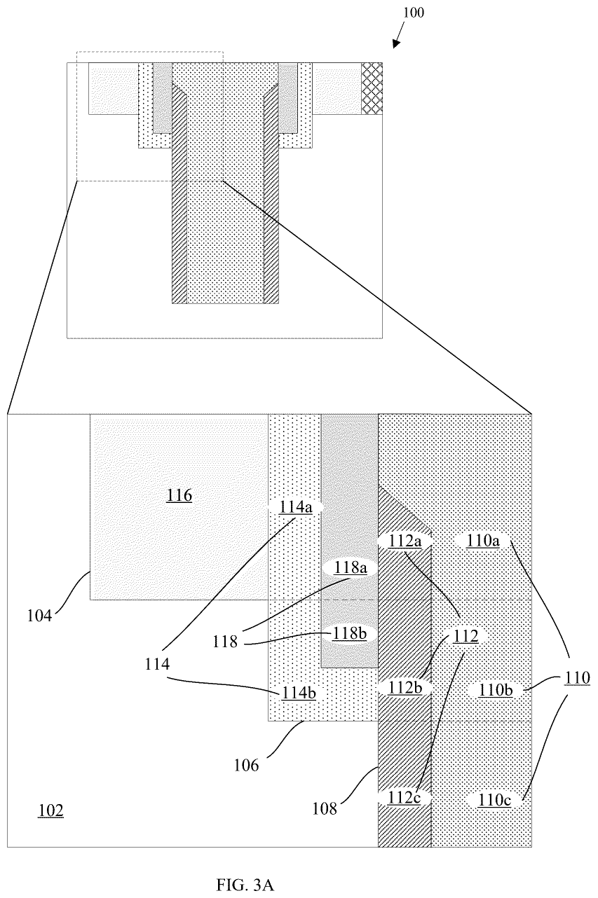

Referring to FIG. 1 and FIG. 3, examples of a structure 100 for isolating integrated circuit (IC) components in a semiconductor device are shown. The structure 100 may include a substrate 102, a first trench 104 in the substrate 102, a second trench 106 in the substrate 102, and a third trench 108 in the substrate 102. The substrate 102 may have a top surface 102t. The substrate 102 may be made of any semiconductor material, such as silicon, germanium, silicon germanium (SiGe), silicon carbide, and those consisting essentially of III-V compound semiconductors, such as GaAs, II-VI compound semiconductors such as ZnSe. The substrate 102 may have an amorphous, polycrystalline, or monocrystalline structure.

The first trench 104 may have sidewalls 104s and a bottom 104b. The second trench 106 may have sidewalls 106s and a bottom 106b. The third trench 108 may have sidewalls 108s and a bottom 108b. The bottom 104b of the first trench 104 may be located at a first depth D1. The first depth D1 may be defined as a vertical distance between the bottom 104b of the first trench 104 and the top surface 102t of the substrate 102. The sidewalls 104s of the first trench 104 may extend from the top surface 102t of the substrate 102 to join the bottom 104b of the first trench 104.

The bottom 106b of the second trench 106 may be located at a second depth D2. The second depth D2 may be lower or deeper than the first depth D1. In other words, the bottom 106b of the second trench 106 may be located lower than the bottom 104b of the first trench 104. The second depth D2 may be defined as a vertical distance between the bottom 106b of the second trench 106 and the top surface 102t of the substrate 102. The sidewalls 106s of the second trench 106 may extend from the bottom 104b of the first trench 104 to join the bottom 106b of the second trench 106.

The bottom 108b of the third trench 108 may be located at a third depth D3. The third depth D3 may be lower or deeper than the second depth D2 and the first depth D1. In other words, the bottom 108b of the third trench 108 may be located lower than the bottom 106b of the second trench 106, and the bottom 104b of the first trench 104. The third depth D3 may be defined as a vertical distance between the bottom 108b of the third trench 108 and the top surface 102t of the substrate 102. The sidewalls 108s of the third trench 108 may extend from the bottom 106b of the second trench 106 to join the bottom 108b of the third trench 108.

The first trench 104 may have a width 104W between the sidewalls 104s of the first trench, the second trench 106 may have a width 106W between the sidewalls 106s of the second trench 106, and the third trench 108 may have a width 108W between the sidewalls 108s of the third trench 108. The width 104W of the first trench 104 may be defined as a lateral distance between oppositely facing sidewalls 104s of the first trench 104. The width 106W of the second trench 106 may be defined as a lateral distance between oppositely facing sidewalls 106s of the second trench 106. The width 108W of the third trench 108 may be defined as a lateral distance between oppositely facing sidewalls 108s of the third trench 108. The second width 106W of the second trench 106 may be smaller than the first width 104W of the first trench 104. The third width 108W of the third trench 108 may be smaller than the second width 106W of the second trench 106, and the first width 104W of the first trench 104.

A dielectric isolation layer 116 may be in the first trench 104. The dielectric isolation layer 116 may be on or directly on the sidewalls 104s and the bottom 104b of the first trench 104. A first dielectric layer 114 may be in at least the second trench 106. The first dielectric layer 114 may be on or directly on the sidewalls 106s and the bottom 106b of the second trench 106. A second dielectric layer 118 may be in the first trench 104 and the second trench 106. The second dielectric layer 118 may be laterally adjacent to the dielectric isolation layer 116 and disposed on the first dielectric layer 114. A third dielectric layer 112 may be in at least the second trench 106 and the third trench 108. The third dielectric layer 112 may be laterally adjacent to the second dielectric layer 118. The third dielectric layer 112 may be on or directly on the sidewalls 108s and the bottom 108b of the third trench 108. A semiconductor layer 110 may be in the first trench 104, the second trench 106, and the third trench 108. The semiconductor layer 110 may be laterally surrounded by at least the third dielectric layer 112. The semiconductor layer 110 may be directly on the bottom 108b of the third trench 108, and may be directly in contact with the substrate 102.

The exemplary dielectric material in the first dielectric layer 114, the second dielectric layer 118, and the third dielectric layer 112 may include, but are not limited to, a nitrogen-containing material such as nitrides of silicon, silicon nitride, silicon oxynitride, or nitrogen-doped silicon carbide, or an oxygen-containing material such as oxides of silicon, silicon dioxide, or silicon-rich silicon oxide. Exemplary dielectric material in the dielectric isolation layer 116 may include, but are not limited to, an oxygen-containing material such as oxides of silicon, tetraethyl orthosilicate (TEOS), or silicon-rich silicon oxide. The third dielectric layer 112 may be of a different material from the second dielectric layer 118. The second dielectric layer 118 may be of a different material from the first dielectric layer 114. In some embodiments, the second dielectric layer 118 may include a nitrogen-containing material. The first dielectric layer 114 and the third dielectric layer 112 may each include an oxygen-containing material. Exemplary material in the semiconductor layer 110 may include, but is not limited to, silicon, germanium, or a silicon germanium (SiGe) composition, and may also have an amorphous, polycrystalline, or monocrystalline structure.

The presence of at least two dielectric layers (e.g., first dielectric layer 114, second dielectric layer 118, third dielectric layer 112) having differing dielectric material with each other in the second trench 106, and being positioned laterally between the semiconductor layer 110 and the substrate 102, may increase the separation distance and the electrical insulation between the semiconductor layer 110 and the substrate 102. The increased separation distance and electrical insulation may provide a higher breakdown voltage limit between the semiconductor layer 110 and the substrate 102.

Referring to FIG. 1 and FIG. 1A, the first dielectric layer 114 may only be present in the second trench 106. The second dielectric layer 118 may have a first portion 118a in the first trench 104 and a second portion 118b in the second trench 106. The third dielectric layer 112 may have a first portion 112a in the first trench 104, a second portion 112b in the second trench 106, and a third portion 112c in the third trench 108. The semiconductor layer 110 may have a first portion 110a in the first trench 104, a second portion 110b in the second trench 106, and a third portion 110c in the third trench 108. The first portion 118a of the second dielectric layer 118 may be laterally between and in direct contact with the dielectric isolation layer 116, the first portion 110a of the semiconductor layer 110, and the first portion 112a of the third dielectric layer 112. The second portion 118b of the second dielectric layer 118 may be laterally between and in direct contact with the first dielectric layer 114 and the second portion 112b of the third dielectric layer 112.

The first portion 112a of the third dielectric layer 112 may be laterally between and in direct contact with the first portion 110a of the semiconductor layer 110 and the first portion 118a of the second dielectric layer 118. The second portion 112b of the third dielectric layer 112 may be laterally between and in direct contact with the second portion 110b of the semiconductor layer 110, the second portion 118b of the second dielectric layer 118, and the first dielectric layer 114. The third portion 112c of the third dielectric layer 112 may be laterally adjacent to and in direct contact with the third portion 110c of the semiconductor layer 110.

Referring to FIG. 3 and FIG. 3A, the first dielectric layer 114 may be present in the first trench 104 and the second trench 106. For example, the first dielectric layer 114 may have a first portion 114a in the first trench 104 and a second portion 114b in the second trench 106. The second dielectric layer 118 may have a first portion 118a in the first trench 104 and a second portion 118b in the second trench 106. The third dielectric layer 112 may have a first portion 112a in the first trench 104, a second portion 112b in the second trench 106, and a third portion 112c in the third trench 108. The semiconductor layer 110 may have a first portion 110a in the first trench 104, a second portion 110b in the second trench 106, and a third portion 110c in the third trench 108.

The first portion 114a of the first dielectric layer 114 may be laterally between and in direct contact with the dielectric isolation layer 116 and the first portion 118a of the second dielectric layer 118. The second portion 114b of the first dielectric layer 114 may be on the sidewalls 106s and the bottom 106b of the second trench 106. The first portion 118a of the second dielectric layer 118 may be laterally between and in direct contact with the first portion 114a of the first dielectric layer 114, the first portion 110a of the semiconductor layer 110, and the first portion 112a of the third dielectric layer 112. The second portion 118b of the second dielectric layer 118 may be laterally between and in direct contact with the second portion 114b of the first dielectric layer 114 and the second portion 112b of the third dielectric layer 112.

The first portion 112a of the third dielectric layer 112 may be laterally between and in direct contact with the first portion 110a of the semiconductor layer 110 and the first portion 118a of the second dielectric layer 118. The second portion 112b of the third dielectric layer 112 may be laterally between and in direct contact with the second portion 110b of the semiconductor layer 110, the second portion 118b of the second dielectric layer 118, and the second portion 114b of the first dielectric layer 114. The third portion 112c of the third dielectric layer 112 may be laterally adjacent to and in direct contact with the third portion 110c of the semiconductor layer 110.

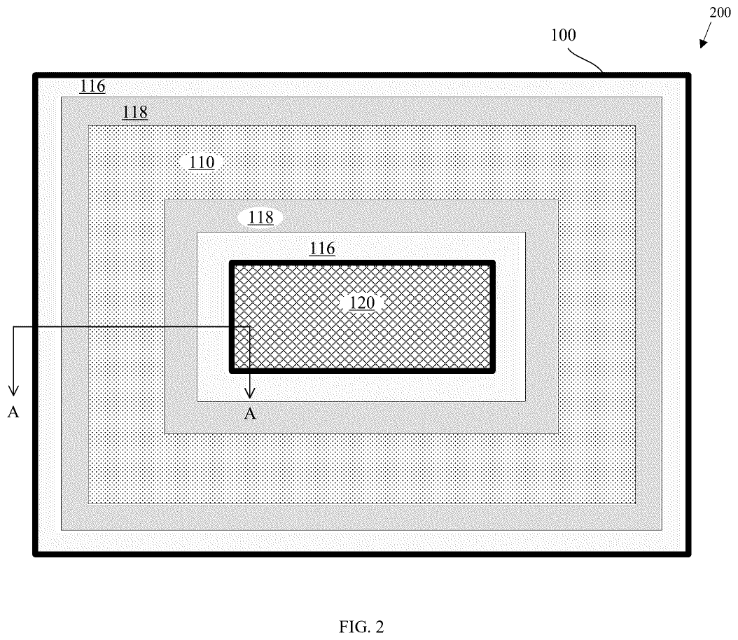

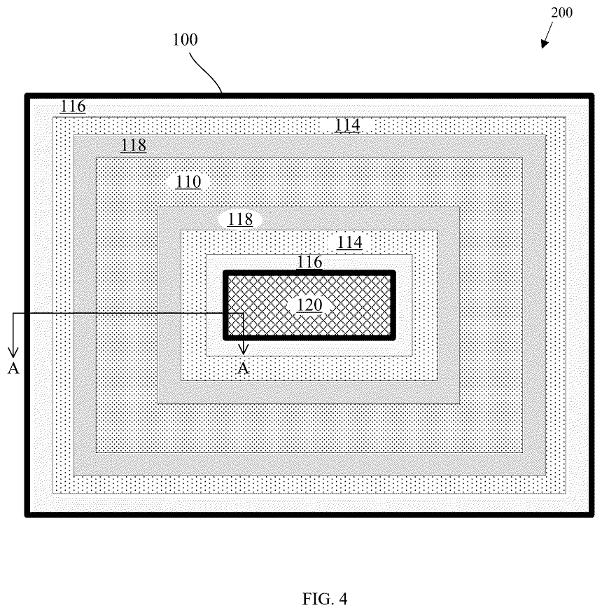

Referring to FIG. 2 and FIG. 4, the structure 100 illustrated in FIG. 1 and FIG. 3, respectively, may function as a trench isolation structure for providing electrical isolation around an integrated circuit (IC) component 120 in a semiconductor device 200. Section line AA in FIG. 2 indicates the cross-section from which the view in FIG. 1 is taken. Section line AA in FIG. 4 indicates the cross-section from which the view in FIG. 3 is taken. In some implementations, the IC component 120 may include an active device such as a transistor capable of operating at high voltages (e.g., above 50V). The structure 100 may laterally enclose or surround the IC component 120 from other adjacent components (not shown) in the semiconductor device 200. For example, the dielectric isolation layer 116 may form a lateral enclosure around the IC component 120.

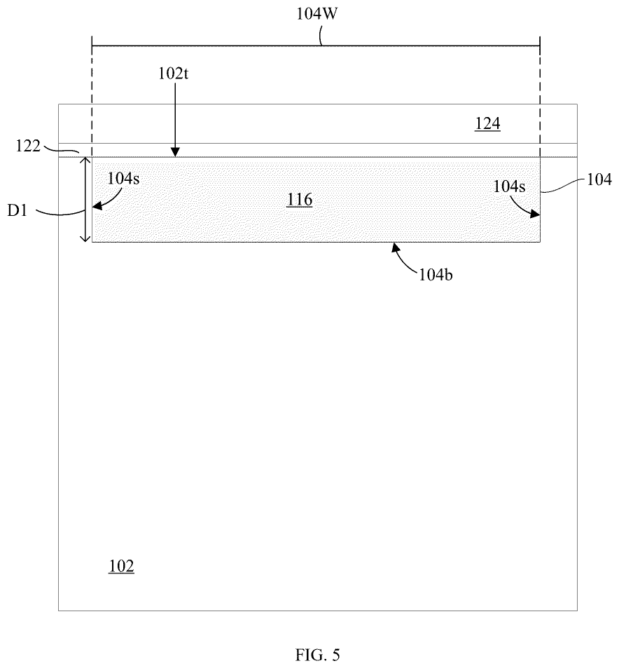

FIGS. 5 through 12 show a set of steps that may be used to create the structure described herein.

As used herein, “deposition techniques” refer to the process of applying a material over another material (or the substrate). Exemplary techniques for deposition include, but are not limited to, spin-on coating, sputtering, chemical vapor deposition (CVD), physical vapor deposition (PVD), molecular beam deposition (MBD), pulsed laser deposition (PLD), liquid source misted chemical deposition (LSMCD), atomic layer deposition (ALD).

Additionally, “patterning techniques” include deposition of material or photoresist, patterning, exposure, development, etching, cleaning, and/or removal of the material or photoresist as required in forming a described pattern, structure, or opening. Examples of techniques for patterning include, but are not limited to, wet etch lithographic processes, dry etch lithographic processes, or direct patterning processes. Such techniques may use mask sets and mask layers.

Referring to FIG. 5, a structure for the fabrication of the structure described in FIG. 1 may include a substrate 102, a first trench 104 formed in the substrate 102, and a dielectric isolation layer 116 formed in the first trench 104. The first trench 104 may be formed with sidewalls 104s and a bottom 104b. The bottom 104b of the first trench 104 may be formed at a first depth D1, in which the first depth D1 may be defined as a vertical distance between the top surface 102t of the substrate 102 and the bottom 104b of the first trench 104. The first trench 104 may be formed to have a width 104W. The width 104W of the first trench 104 may be defined as a lateral distance between oppositely facing sidewalls 104s of the first trench 104.

The first trench 104 may be formed by patterning the substrate 102 using patterning techniques to form openings (not shown) and then filling the openings with the dielectric isolation layer 116 using deposition techniques described herein. The dielectric isolation layer 116 may be formed directly on the sidewalls 104s and the bottom 104b of the first trench 104. Pad dielectric layers 122, 124 may be formed on the substrate 102, using deposition techniques described herein, such that it covers the first trench 104 and the dielectric isolation layer 116. In an embodiment, the pad dielectric layer 122 may be an oxide layer while the pad dielectric layer 124 may be a nitride layer.

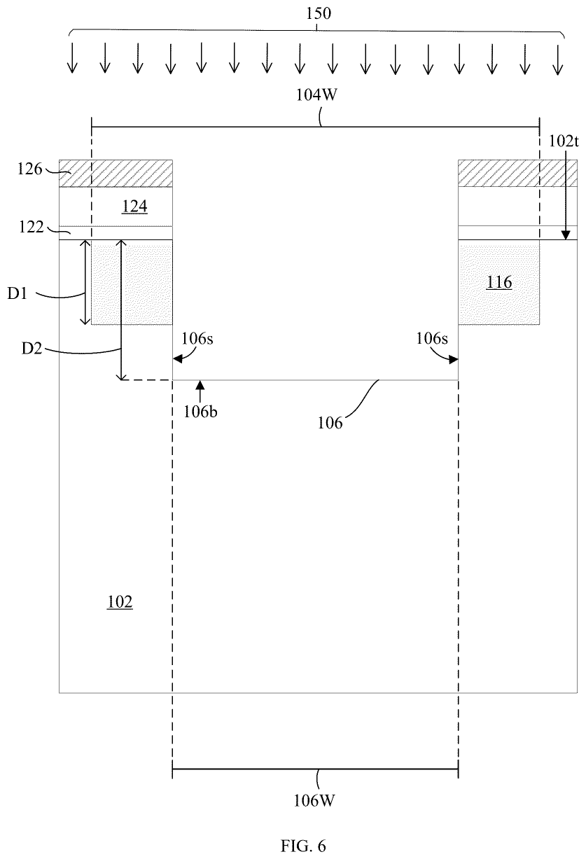

Referring to FIG. 6, a second trench 106 may be formed in the substrate 102. The second trench 106 may be formed using an etching process 150 with the use of a patterned mask layer 126. The etching process 150 may etch away portions of the pad dielectric layers 122, 124, a portion of the dielectric isolation layer 116 in the first trench 104, and a portion of the substrate 102. The patterned mask layer 126 may be formed on the pad dielectric layer 124 using deposition techniques described herein. The patterned mask layer 126 may have an opening (not shown) defined therein for the etching of the pad dielectric layers 122, 124, the dielectric isolation layer 116, and the substrate 102. The second trench 106 may be formed with sidewalls 106s and a bottom 106b. The bottom 106b of the second trench 106 may be formed at a second depth D2, in which the second depth D2 may be defined as a vertical distance between the top surface 102t of the substrate 102 and the bottom 106b of the second trench 106. The second trench 106 may also be formed to have a width 106W. The width 106W of the second trench 106 may be defined as a lateral distance between oppositely facing sidewalls 106s of the second trench 106. The width 106W may correspond to a width of the opening defined in the patterned mask layer 126.

The patterned mask layer 126 may be removed after the etching process 150. An opening (not shown) may be formed in the pad dielectric layers 122, 124 and the dielectric isolation layer 116 after the etching process 150. As the substrate 102 is etched during the etching process 150, the sidewalls 106s of the second trench 106 may be formed, which extend from the bottom 104b of the first trench 104 into the substrate 102. The duration of the etching process 150 may control the second depth D2 of the second trench 106, for example, a longer etching process 150 may form a deeper depth D2, and vice versa. The depth D2 may be formed to be larger or deeper than the depth D1.

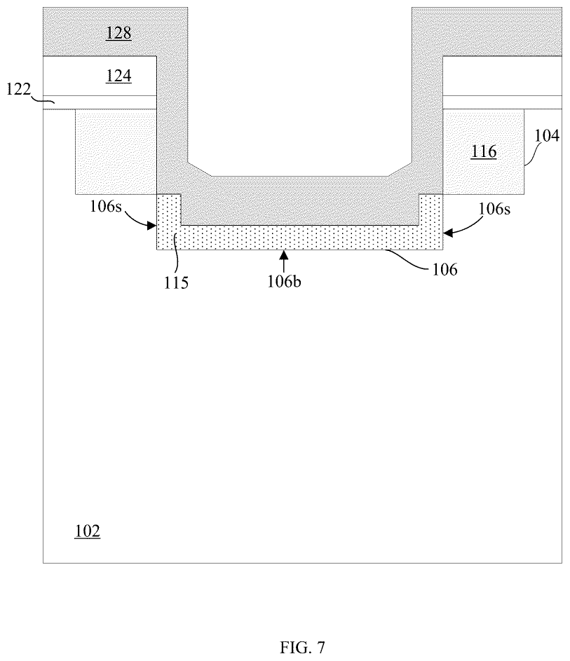

Referring to FIG. 7, a first dielectric material layer 115 may be formed only within the second trench 106, for example, by an oxidation process. The oxidation process may include thermal oxidation of a portion of the substrate 102 being exposed to the sidewalls 106s and the bottom 106b of the second trench 106. The first dielectric material layer 115 may be formed directly on the sidewalls 106s and the bottom 106b of the second trench 106. A second dielectric material layer 128 may be formed, using deposition techniques described herein, on or directly on at least the first dielectric material layer 115 and the dielectric isolation layer 116. As shown in FIG. 7, the second dielectric material layer 128 may also be formed on the pad dielectric layers 122, 124. The second dielectric material layer 128 may be of a different dielectric material from the first dielectric material layer 115.

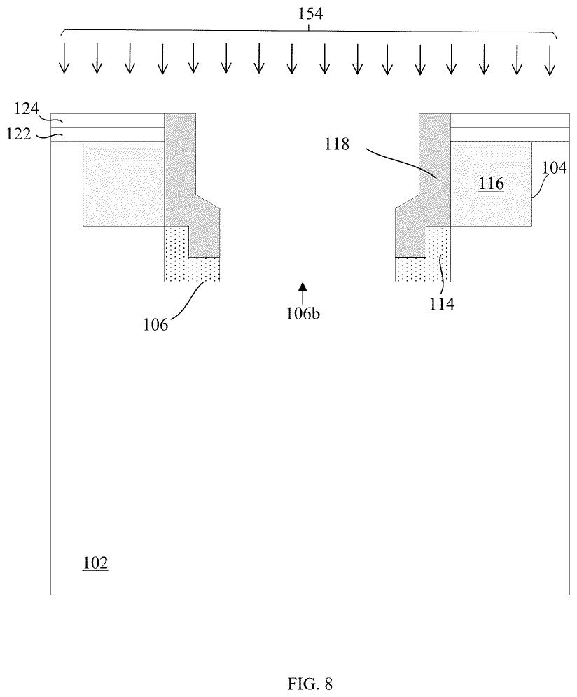

Referring to FIG. 8, a first dielectric layer 114 may be formed only within the second trench 106, and a second dielectric layer 118 may be formed in the first trench 104 and the second trench 106, with the use of an etching process 154. The etching process 154 may involve a directional etching process where the first dielectric material layer 115 and the second dielectric material layer 128 (as shown in FIG. 7) may be etched along a vertical direction. The first dielectric layer 114 and the second dielectric layer 118 may be respectively formed by etching the first dielectric material layer 115 and the second dielectric material layer 128. The etching process 154 may expose a portion of the bottom 106b of the second trench 106 and the pad dielectric layer 124. The exposed portion of the bottom 106b of the second trench 106 may have an area that directly contacts the substrate 102. The etching process 154 may also partially etch the pad dielectric layer 124 such that the thickness of the pad dielectric layer 124 may be decreased after the etching process 154.

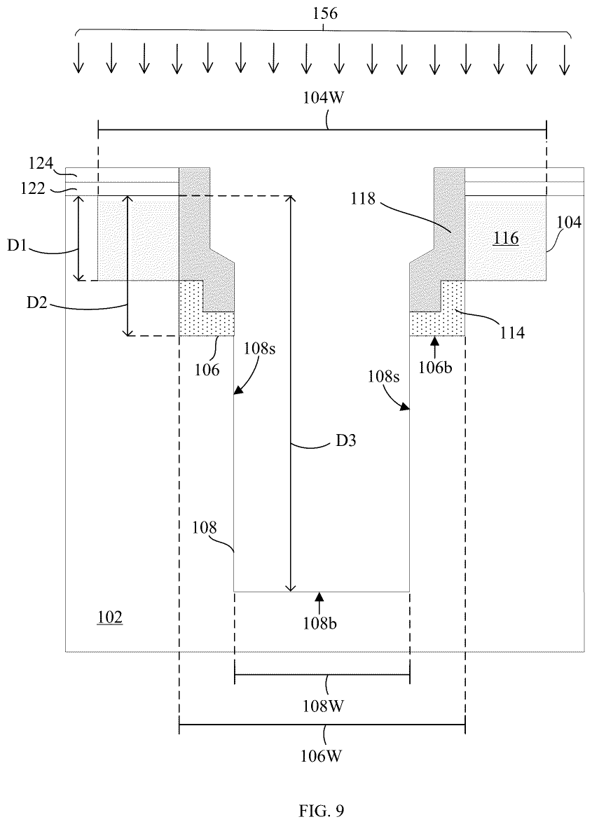

Referring to FIG. 9, a third trench 108 may be formed in the substrate 102. The third trench 108 may be formed by performing an etching process 156 to remove a portion of the substrate 102 that is aligned vertically below the exposed portion of the bottom 106b of the second trench 106. The third trench 108 may be formed with sidewalls 108s and a bottom 108b. The bottom 108b of the third trench 108 may be formed at a third depth D3, in which the third depth D3 may be defined as a vertical distance between the top surface 102t of the substrate 102 and the bottom 108b of the third trench 108. The third trench 108 may also be formed to have a width 108W. The width 108W of the third trench 108 may be defined as a lateral distance between oppositely facing sidewalls 108s of the third trench 108. The area at the bottom 108b of the third trench 108 may correspond to, or be defined by, the area at the exposed portion of the bottom 106b of the second trench 106, as described in FIG. 8. As the portion of the substrate 102 aligned vertically below the exposed portion of the bottom 106b of the second trench 106 is etched during the etching process 156, the sidewalls 108s of the third trench 108 may be formed, which extend from the bottom 106b of the second trench 106 into the substrate 102. The duration of the etching process 156 may control the third depth D3 of the third trench 108, for example, a longer etching process 156 may form a deeper depth D3, and vice versa. The depth D3 may be formed to be larger or deeper than the depth D2.

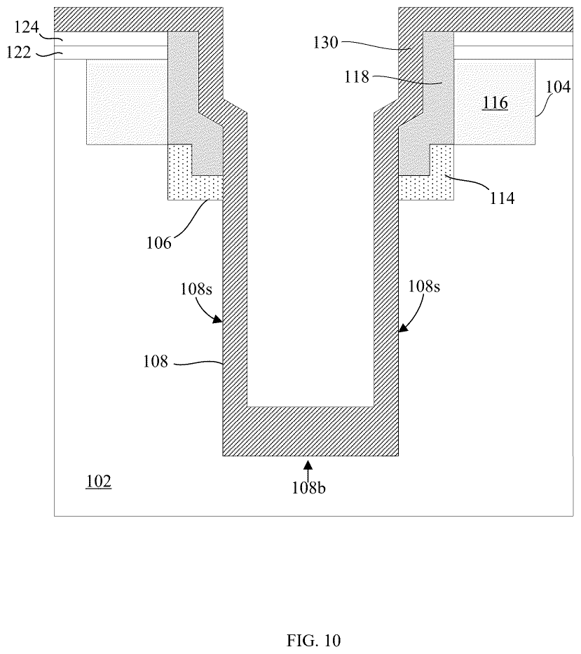

Referring to FIG. 10, a third dielectric material layer 130 may be formed in the first trench 104, the second trench 106, the third trench 108, and may be formed on or directly on the sidewalls 108s and the bottom 108b of the third trench 108, the first dielectric layer 114, and the second dielectric layer 118. The deposition techniques described herein may be used in the formation of the third dielectric material layer 130. The third dielectric material layer 130 may also be formed on the pad dielectric layer 124. The third dielectric material layer 130 may be of a different material from the second dielectric layer 118.

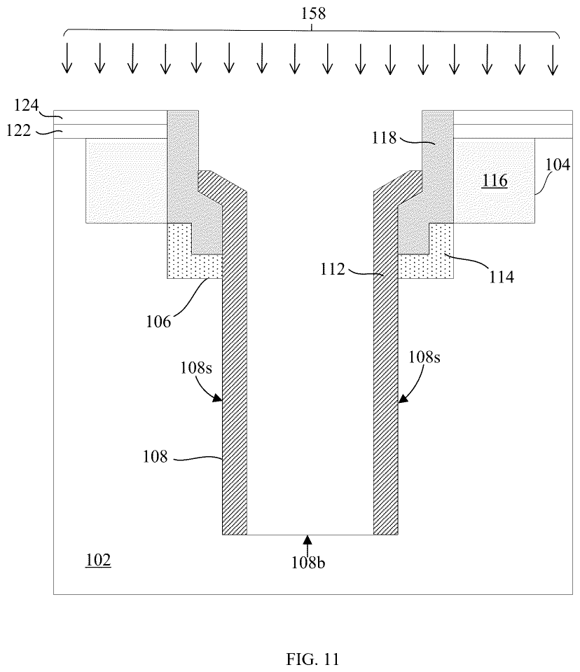

Referring to FIG. 11, a third dielectric layer 112 may be formed in the first trench 104, the second trench 106, and the third trench 108, with the use of an etching process 158. The etching process 158 may be performed to etch and partially remove the third dielectric material layer 130. For example, the etching process 158 may involve a directional etching process where the third dielectric material layer 130 (as shown in FIG. 10) may be etched along a vertical direction to expose a portion of the bottom 108b of the third trench 108. The exposed portion of the bottom of 108b of the third trench 108 may have an area that directly contacts the substrate 102. The etching process 158 may also remove portions of the third dielectric material layer 130 covering the pad dielectric layer 124 such that the pad dielectric layer 124 is exposed.

The etching process 158 may be selective to the material of the third dielectric material layer 130, and the second dielectric layer 118 underlying the third dielectric material layer 130 may be partially exposed as the third dielectric material layer 130 is being etched. The second dielectric layer 118 may not be etched or minimally etched relative to the etching of the third dielectric material layer 130 during the etching process 158. Due to the difference in the etch selectivity between the material in the third dielectric material layer 130 and the second dielectric layer 118, the second dielectric layer 118 may function as a mask to protect the underlying first dielectric layer 114 from the etching process 158, and consequently, the first dielectric layer 114 may not be etched after the etching process 158.

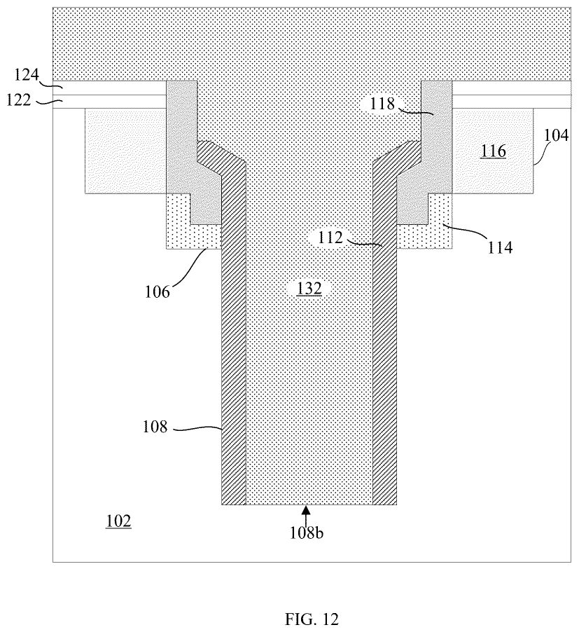

Referring to FIG. 12, a semiconductor material layer 132 may be formed in the first trench 104, the second trench 106, and the third trench 108, for example, using deposition techniques described herein. The semiconductor material layer 132 may also be formed outside of the trenches 104, 106, 108 such that the semiconductor material layer 132 is formed on the pad dielectric layer 124. Within the trenches 104, 106, 108, the semiconductor material layer 132 may be formed on or directly on the second dielectric layer 118, the third dielectric layer 112, and the exposed portion of the bottom 108b of the third trench 108 described in FIG. 11.

The structure shown in FIG. 12 may undergo further processing to form the structure shown in FIG. 1. For example, a chemical mechanical planarization (CMP) process and one or more etching processes may be performed on the structure shown in FIG. 12 to remove portions of the semiconductor material layer 132 formed outside of the trenches 104, 106, 108, and then subsequently remove the pad dielectric layers 122, 124, such that the dielectric isolation layer 116 is exposed. The semiconductor layer 110 shown in FIG. 1 may be formed by the remaining semiconductor material layer 132 within the trenches 104, 106, 108.

FIGS. 5 through 6 and FIGS. 13 through 18 show another set of steps that may be used to create the structure described herein.

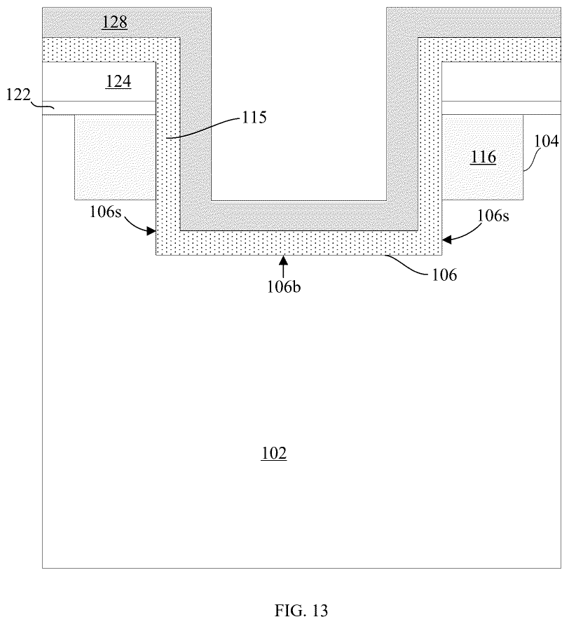

Referring to FIG. 13 (the structure shown in FIG. 13 continues from the structure shown in FIG. 6), a first dielectric material layer 115 may be formed in the first trench 104 and the second trench 106, using the deposition techniques described herein. The first dielectric material layer 115 may, for example, be deposited on or directly on the sidewalls 106s and the bottom 106b of the second trench 106, and the dielectric isolation layer 116. The first dielectric material may also be formed over the pad dielectric layers 122, 124. A second dielectric material layer 128 may be formed in the trenches 104, 106 and on the first dielectric material layer 115, using the deposition techniques described herein. The second dielectric material layer 128 may be of a different dielectric material from the first dielectric material layer 115.

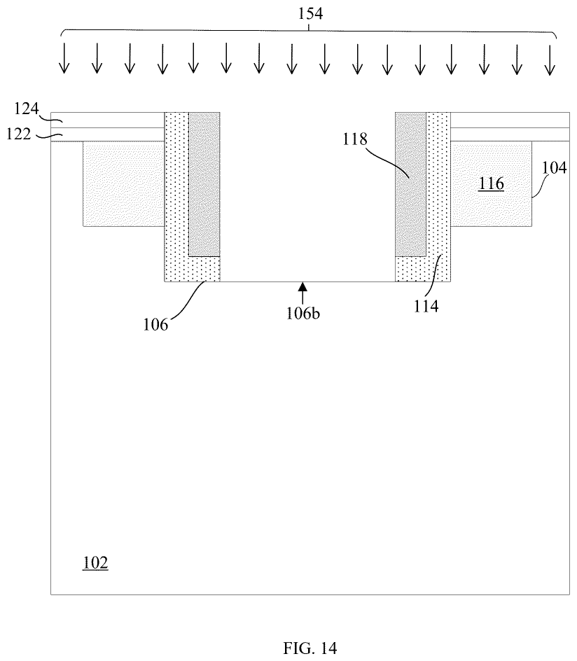

Referring to FIG. 14, a first dielectric layer 114 and a second dielectric layer 118 may be formed in the first trench 104 and the second trench 106 by performing an etching process 154. The etching process 154 may involve a directional etching process where the first dielectric material layer 115 and the second dielectric material layer 128 (as shown in FIG. 13) may be etched along a vertical direction. The first dielectric layer 114 and the second dielectric layer 118 may be respectively formed by etching the first dielectric material layer 115 and the second dielectric material layer 128. The resulting first dielectric layer 114 may be laterally between and may separate the dielectric isolation layer 116 and the second dielectric layer 118. The etching process 154 may expose a portion of the bottom 106b of the second trench 106 and the pad dielectric layer 124. The exposed portion of the bottom 106b of the second trench 106 may have an area that directly contacts the substrate 102. The etching process 154 may also partially etch the pad dielectric layer 124 such that the thickness of the pad dielectric layer 124 may be decreased after the etching process 154.

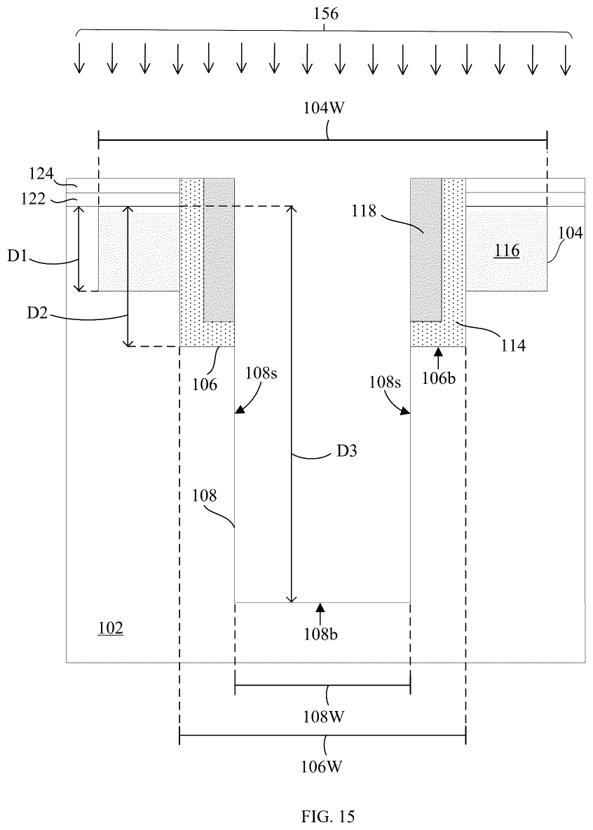

Referring to FIG. 15, a third trench 108 may be formed in the substrate 102. The third trench 108 may be formed by performing an etching process 156 to remove a portion of the substrate 102 that is aligned vertically below the exposed portion of the bottom 106b of the second trench 106. The third trench 108 may be formed with sidewalls 108s and a bottom 108b. The bottom 108b of the third trench 108 may be formed at a third depth D3, in which the third depth D3 may be defined as a vertical distance between the top surface 102t of the substrate 102 and the bottom 108b of the third trench 108. The third trench 108 may also be formed to have a width 108W. The width 108W of the third trench 108 may be defined as a lateral distance between oppositely facing sidewalls 108s of the third trench 108. The area at the bottom 108b of the third trench 108 may correspond to, or be defined by, the area at the exposed portion of the bottom 106b of the second trench 106, as described in FIG. 14. As the portion of the substrate 102 aligned vertically below the exposed portion of the bottom 106b of the second trench 106 is etched during the etching process 156, the sidewalls 108s of the third trench 108 may be formed, which extend from the bottom 106b of the second trench 106 into the substrate 102. The duration of the etching process 156 may control the third depth D3 of the third trench 108, for example, a longer etching process 156 may form a deeper depth D3, and vice versa. The depth D3 may be formed to be larger or deeper than the depth D2.

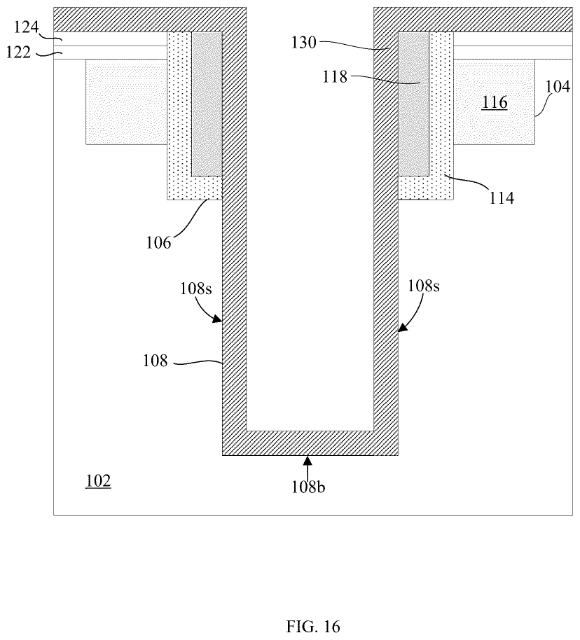

Referring to FIG. 16, a third dielectric material layer 130 may be formed in the first trench 104, the second trench 106, and the third trench 108, and may be formed on or directly on the sidewalls 108s and the bottom 108b of the third trench 108, the first dielectric layer 114, and the second dielectric layer 118. The deposition techniques described herein may be used in the formation of the third dielectric material layer 130. The third dielectric material layer 130 may also be formed on the pad dielectric layer 124. The third dielectric material layer 130 may be of a different material from the second dielectric layer 118.

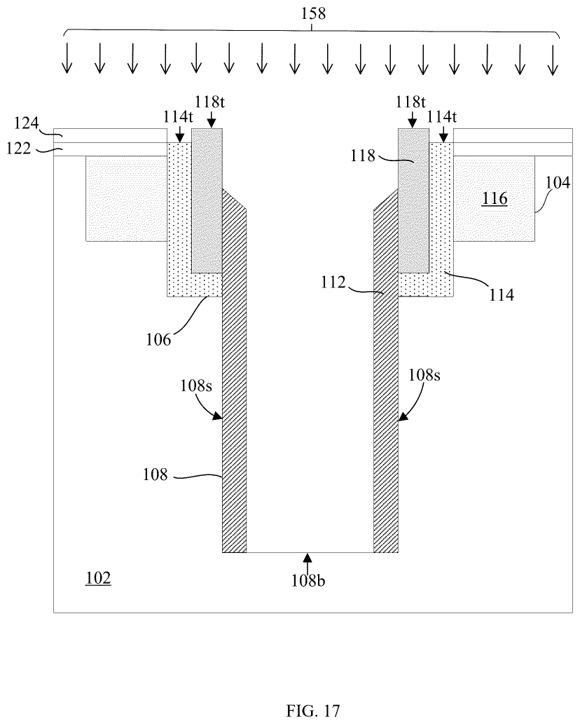

Referring to FIG. 17, a third dielectric layer 112 may be formed in the first trench 104, the second trench 106, and the third trench 108, with the use of an etching process 158. The etching process 158 may be performed to etch and partially remove the third dielectric material layer 130. For example, the etching process 158 may involve a directional etching process where the third dielectric material layer 130 (as shown in FIG. 16) may be etched along a vertical direction to expose a portion of the bottom 108b of the third trench 108. The exposed portion of the bottom of 108b of the third trench 108 may have an area that directly contacts the substrate 102. The etching process 158 may also remove portions of the third dielectric material layer 130 covering the pad dielectric layer 124 such that the pad dielectric layer 124 is exposed.

The etching process 158 may be selective to the material of the third dielectric material layer 130, and the second dielectric layer 118 underlying the third dielectric material layer 130 may be partially exposed as the third dielectric material layer 130 is being etched. The second dielectric layer 118 may not be etched or minimally etched relative to the etching of the third dielectric material layer 130 during the etching process 158. The etching of the third dielectric material layer 130 may partially expose a top surface 114t of the first dielectric layer 114 that is laterally between the pad dielectric layers 122, 124 and the second dielectric layer 118. The vertical directional etching in the etching process 158 may etch onto the top surface 114t of the first dielectric layer 114 such that the top surface 114t of the first dielectric layer 114 is recessed to a level below a top surface 118t of the second dielectric layer 118. Due to the difference in the etch selectivity between the material in the third dielectric material layer 130 and the second dielectric layer 118, the second dielectric layer 118 may function as a mask to protect the portion of the first dielectric layer 114 in the second trench 106 from the etching process 158. As a result, the portion of the first dielectric layer 114 in the second trench 106 may not be etched after the etching process 158.

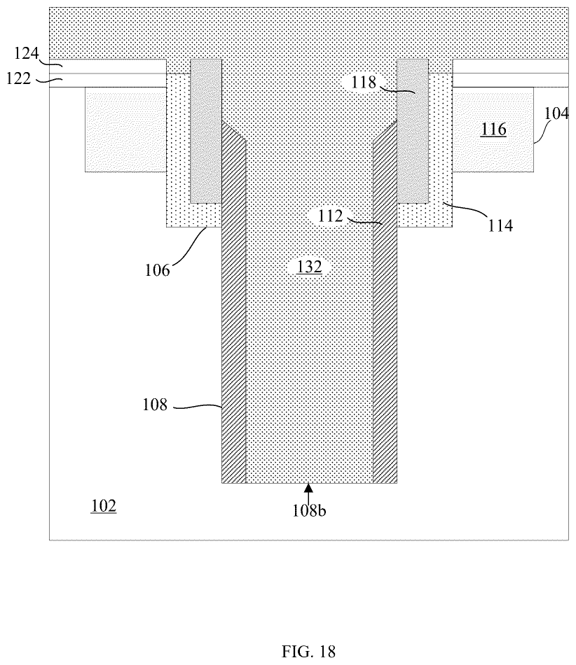

Referring to FIG. 18, a semiconductor material layer 132 may be formed in the first trench 104, the second trench 106, and the third trench 108, for example, using deposition techniques described herein. The semiconductor material layer 132 may also be formed outside of the trenches 104, 106, 108 such that the semiconductor material layer 132 is formed on the pad dielectric layer 124. Within the trenches 104, 106, 108, the semiconductor material layer 132 may be formed on or directly on the second dielectric layer 118, the third dielectric layer 112, and the exposed portion of the bottom 108b of the third trench 108 described in FIG. 17.

The structure shown in FIG. 18 may undergo further processing to form the structure shown in FIG. 3. For example, a chemical mechanical planarization (CMP) process and one or more etching processes may be performed on the structure shown in FIG. 18 to remove portions of the semiconductor material layer 132 formed outside of the trenches 104, 106, 108, and then subsequently remove the pad dielectric layers 122, 124, such that the dielectric isolation layer 116 is exposed. The semiconductor layer 110 shown in FIG. 3 may be formed by the remaining semiconductor material layer 132 within the trenches 104, 106, 108.

Throughout this disclosure, it is to be understood that if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in an embodiment” herein do not necessarily all refer to the same embodiment, occurrences of the phrase “in an implementation” herein do not necessarily all refer to the same implementation, and occurrences of the phrase “in an example” herein do not necessarily all refer to the same example.

The descriptions of the various embodiments of the present disclosure have been presented for purposes of illustration, but are not intended to be exhaustive or limited to the embodiments disclosed. Modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. Furthermore, there is no intention to be bound by any theory presented in the preceding background or the following detailed description. Additionally, the various tasks and processes described herein may be incorporated into a more comprehensive procedure or process having additional functionality not described in detail herein.

References herein to terms modified by language of approximation, such as “about”, “approximately”, and “substantially”, are not to be limited to the precise value specified. The language of approximation may correspond to the precision of an instrument used to measure the value and, unless otherwise dependent on the precision of the instrument, may indicate +/-10% of the stated value(s).

As will be readily apparent to those skilled in the art upon a complete reading of the present application, the semiconductor isolation structures and methods of manufacture disclosed herein may be used in association with a variety of different integrated circuit products, including, but not limited to, SiGe based devices, CMOS, high voltage semiconductor devices, bipolar, and a combination of bipolar and CMOS (BiCMOS) semiconductor devices, etc.

What is claimed is:

1. A structure comprising:
a substrate;
a first trench in the substrate, the first trench having a bottom located at a first depth;
a second trench in the substrate, the second trench having a bottom located at a second depth, the second depth is lower than the first depth, the second trench also having sidewalls extending from the bottom of the first trench to join the bottom of the second trench;
a third trench in the substrate, the third trench having a bottom located at a third depth, the third depth is lower than the second depth, the third trench also having sidewalls extending from the bottom of the second trench to join the bottom of the third trench;
a dielectric isolation layer in the first trench;
a first dielectric layer on the sidewalls and the bottom of the second trench;
a second dielectric layer laterally adjacent to the dielectric isolation layer and disposed on the first dielectric layer, wherein the second dielectric layer is of a different material from the first dielectric layer;
a third dielectric layer laterally adjacent to the second dielectric layer, wherein the third dielectric layer is of a different material from the second dielectric layer; and
a semiconductor layer in the first trench, the second trench, and the third trench.

2. The structure of claim 1, wherein the first dielectric layer is only in the second trench.

3. The structure of claim 2, wherein the second dielectric layer has a first portion in the first trench and a second portion in the second trench, the first portion of the second dielectric layer is in direct contact with the dielectric isolation layer and the semiconductor layer.

4. The structure of claim 3, wherein the second portion of the second dielectric layer is laterally between and in direct contact with the first dielectric layer and the third dielectric layer.

5. The structure of claim 4, wherein the semiconductor layer is in direct contact with the substrate.

6. The structure of claim 2, wherein the second dielectric layer includes a nitrogen-containing material, and the first dielectric layer includes an oxygen-containing material.

7. The structure of claim 1, wherein the first trench has sidewalls, and the structure further comprises:
a first width between the sidewalls of the first trench;
a second width between the sidewalls of the second trench, the second width is smaller than the first width; and
a third width between the sidewalls of the third trench, the third width is smaller than the second width.

8. A structure comprising:
a substrate;
a first trench in the substrate, the first trench having a bottom located at a first depth;
a second trench in the substrate, the second trench having a bottom located at a second depth, the second depth is lower than the first depth, the second trench also having sidewalls extending from the bottom of the first trench to join the bottom of the second trench;
a third trench in the substrate, the third trench having a bottom located at a third depth, the third depth is lower than the second depth, the third trench also having sidewalls extending from the bottom of the second trench to join the bottom of the third trench;
a dielectric isolation layer in the first trench;
a first dielectric layer on the sidewalls and the bottom of the second trench, the first dielectric layer is in direct contact with the dielectric isolation layer;
a second dielectric layer in direct contact with the first dielectric layer, wherein the second dielectric layer is of a different material from the first dielectric layer;
a third dielectric layer in direct contact with the second dielectric layer, wherein the third dielectric layer is of a different material from the second dielectric layer; and
a semiconductor layer in the first trench, the second trench, and the third trench.

9. The structure of claim 8, wherein the second dielectric layer has a first portion in the first trench and a second portion in the second trench, the second portion of the second dielectric layer is laterally between the first dielectric layer and the third dielectric layer.

10. The structure of claim 9, wherein the semiconductor layer is in direct contact with the first portion of the second dielectric layer.

11. The structure of claim 9, wherein the second dielectric layer includes a nitrogen-containing material, and the first dielectric layer includes an oxygen-containing material.

12. The structure of claim 8, wherein the first trench has sidewalls, and the structure further comprises:
a first width between the sidewalls of the first trench;
a second width between the sidewalls of the second trench, the second width is smaller than the first width; and
a third width between the sidewalls of the third trench, the third width is smaller than the second width.

13. A structure comprising:
a substrate;
a first trench in the substrate, the first trench having sidewalls and a bottom located at a first depth;
a second trench in the substrate, the second trench having a bottom located at a second depth, the second depth is lower than the first depth, the second trench also having sidewalls extending from the bottom of the first trench to join the bottom of the second trench;
a third trench in the substrate, the third trench having a bottom located at a third depth, the third depth is lower than the second depth, the third trench also having sidewalls extending from the bottom of the second trench to join the bottom of the third trench;
a first width between the sidewalls of the first trench;
a second width between the sidewalls of the second trench, the second width is smaller than the first width;
a third width between the sidewalls of the third trench, the third width is smaller than the second width;
a dielectric isolation layer in the first trench;
a first dielectric layer on the sidewalls and the bottom of the second trench;
a second dielectric layer laterally adjacent to the dielectric isolation layer and disposed on the first dielectric layer, wherein the second dielectric layer is of a different material from the first dielectric layer;
a third dielectric layer laterally adjacent to the second dielectric layer, wherein the third dielectric layer is of a different material from the second dielectric layer; and
a semiconductor layer in the first trench, the second trench, and the third trench.

14. The structure of claim 13, wherein the first dielectric layer is only in the second trench.

15. The structure of claim 14, wherein the second dielectric layer has a first portion in the first trench and a second portion in the second trench, the first portion of the second dielectric layer is in direct contact with the dielectric isolation layer and the semiconductor layer.

16. The structure of claim 15, wherein the second portion of the second dielectric layer is laterally between and in direct contact with the first dielectric layer and the third dielectric layer.

17. The structure of claim 13, wherein the first dielectric layer is in direct contact with the dielectric isolation layer.

18. The structure of claim 17, wherein the second dielectric layer has a first portion in the first trench and a second portion in the second trench, the second portion of the second dielectric layer is laterally between the first dielectric layer and the third dielectric layer.

19. The structure of claim 18, wherein the semiconductor layer is in direct contact with the first portion of the second dielectric layer.

20. The structure of claim 13, wherein the second dielectric layer includes a nitrogen-containing material, and the first dielectric layer includes an oxygen-containing material.
